(19) United States
(12) Patent Application Publication
(10) Pub. No.: US 2025/0382553 A1
(43) Pub. Date: Dec. 18, 2025

(54) PHOTORESIST STRIPPER AND METHOD FOR USING THE SAME

(71) Applicant: NAN YA PLASTICS CORPORATION, TAIPEI (TW)

(72) Inventors: CHING-YAO YUAN, TAIPEI (TW); CHENG-LI CHAO, TAIPEI (TW); Hsiu-Ping Lai, TAIPEI (TW)

(21) Appl. No.: 18/801,689

(22) Filed: Aug. 12, 2024

(30) Foreign Application Priority Data
Jun. 18, 2024 (TW) 113122422

(51) Int. Cl. C11D 3/28; C11D 1/34; C11D 3/04; C11D 3/43; C11D 7/32; C11D 7/50; H05K 3/00

(52) U.S. Cl. CPC C11D 3/28; C11D 1/345; C11D 3/044; C11D 3/43; C11D 7/3281; C11D 7/5022; H05K 3/0079

(57) ABSTRACT

A photoresist stripper and a method for using the same are provided. The photoresist stripper includes a first stripper and a second stripper. An organic base is absent from the photoresist stripper. The first stripper includes an inorganic base, 1 wt % to 15 wt % of a first azole compound, 2 wt % to 10 wt % of a surfactant, and water. The inorganic base includes potassium hydroxide and sodium hydroxide. The second stripper includes 30 wt % to 80 wt % of an ether alcohol solvent, 1 wt % to 15 wt % of a second azole compound, and water. A concentration of the inorganic base in the first stripper ranges from 30 g/L to 45 g/L.

### CROSS-REFERENCE TO RELATED PATENT APPLICATION

This application claims the benefit of priority to Taiwan Patent Application No. 113122422, filed on Jun. 18, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a photoresist stripper and a method for using the same, and more particularly to a photoresist stripper without organic amines and a method for using the same.

### BACKGROUND OF THE DISCLOSURE

A manufacturing method of a circuit board includes steps of: forming a copper surface; applying a photoresist onto the copper surface; developing the photoresist to form a dry film that partially covers the copper surface; etching the exposed copper surface; and stripping the dry film.

During the stripping step, a stripper is usually used to remove the dry film that covers fine circuits. The conventional stripper primarily contains sodium hydroxide, and has advantages of low costs and a high stripping rate. However, film scraps produced by the stripping step are relatively large. For the fine circuits, there is the problem of incomplete stripping, which may result in the circuit board failing to pass quality control.

As such, another stripper that contains an inorganic base and an organic base is available on the market. The organic base is an amine compound, such as ethanolamine or ethylenediamine. The coexistence of the inorganic base and the organic base enables the stripper to have an improved stripping effect. However, due to the presence of the organic amine, the stripper has an irritating odor, which leaves room for improvement.

Therefore, how to exclude the use of the organic amine and maintain a certain level of the stripping effect through improvements in composition has become one of the important issues to be solved in the relevant industry.

### SUMMARY OF THE DISCLOSURE

In response to the above-referenced technical inadequacy, the present disclosure provides a photoresist stripper and a method for using the same.

In order to solve the above-mentioned problem, one of the technical aspects adopted by the present disclosure is to provide a photoresist stripper. An organic base is absent from the photoresist stripper. The photoresist stripper includes a first stripper and a second stripper. The first stripper includes an inorganic base, 1 wt % to 15 wt % of a first azole compound, 2 wt % to 10 wt % of a surfactant, and water. The inorganic base includes potassium hydroxide and sodium hydroxide. The second stripper includes 30 wt % to 80 wt % of an ether alcohol solvent, 1 wt % to 15 wt % of a second azole compound, and water. A concentration of the inorganic base in the first stripper ranges from 30 g/L to 45 g/L.

In one of the possible or preferred embodiments, a weight ratio of the potassium hydroxide to the sodium hydroxide ranges from 2.5 to 6.0.

In one of the possible or preferred embodiments, the first azole compound is selected from the group consisting of: benzotriazole, mercaptobenzothiazole, tolyltriazole, and 5-phenyltetrazole.

In one of the possible or preferred embodiments, the second azole compound is selected from the group consisting of: benzotriazole, mercaptobenzothiazole, tolyltriazole, and 5-phenyltetrazole.

In one of the possible or preferred embodiments, the surfactant is selected from the group consisting of: sodium lauryl sulfate, octadecyltrimethylammonium hydroxide, alkyl dimethylphenyl ammonium hydroxide, alkyl sulfate ester salt, phosphate ester salt, sulfosuccinate ester, glutamate, lauryl betaine, cocamidopropyl betaine, and polyoxyethylene lauryl ether potassium phosphate.

In one of the possible or preferred embodiments, the ether alcohol solvent is selected from the group consisting of: diethylene glycol butyl ether, diethylene glycol methyl ether, diethylene glycol propyl ether, dipropylene glycol propyl ether, propylene glycol n-butyl ether, diethylene glycol dibutyl ether, tripropylene glycol methyl ether, ethylene glycol butyl ether, ethylene glycol propyl ether, diethylene glycol hexyl ether, diethylene glycol diethyl ether, and diethylene glycol dimethyl ether.

In order to solve the above-mentioned problem, another one of the technical aspects adopted by the present disclosure is to provide a method for using a photoresist stripper. The method includes: applying a first stripper onto a circuit board, in which an organic base is absent from the first stripper, the first stripper includes an inorganic base, 1 wt % to 15 wt % of a first azole compound, 2 wt % to 10 wt % of a surfactant, and water, and a concentration of the inorganic base in the first stripper ranges from 30 g/L to 45 g/L; applying a second stripper onto the circuit board, in which an organic base is absent from the second stripper, and the second stripper includes 30 wt % to 80 wt % of an ether alcohol solvent, 1 wt % to 15 wt % of a second azole compound, and water; mixing the first stripper and the second stripper at a weight ratio ranging from 1:1 to 2:3, and adding 1 time to 2.5 times of water to form a third stripper; and applying the third stripper onto the circuit board.

In one of the possible or preferred embodiments, the first stripper, the second stripper, and the third stripper are applied to the circuit board by spraying.

In order to solve the above-mentioned problem, yet another one of the technical aspects adopted by the present disclosure is to provide a photoresist stripper. An organic base is absent from the photoresist stripper. The photoresist stripper includes: an inorganic base, in which the inorganic base includes potassium hydroxide and sodium hydroxide; 1 wt % to 5 wt % of an azole compound; 1 wt % to 10 wt % of a surfactant; 30 wt % to 80 wt % of an ether alcohol solvent; and water. A concentration of the inorganic base in the photoresist stripper ranges from 1.5 g/L to 26 g/L.

In one of the possible or preferred embodiments, the azole compound includes at least one of benzotriazole, mercaptobenzothiazole, tolyltriazole, and 5-phenyltetrazole.

Therefore, in the photoresist stripper and the method for using the same provided by the present disclosure, by virtue of “the first stripper including the inorganic base, the first azole compound, and the surfactant” and “the second stripper including the ether alcohol solvent and the second azole compound,” the photoresist stripper can have a good stripping effect without the addition of the organic base.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for using a photoresist stripper according to the present disclosure; and

FIG. 2 is a schematic view showing a circuit board undergoing a stripping treatment.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In the present disclosure, by adjusting a composition and improving a use method, a photoresist stripper can still achieve a good stripping effect without an organic base (an amine compound). Hence, the photoresist stripper of the present disclosure not only can replace the existing stripper that generates irritating odors but can also be applied to a circuit board having fine circuits with a width of 3 mils or more.

The photoresist stripper of the present disclosure is a two-part photoresist stripper that includes a first stripper and a second stripper that are individually packaged. The first stripper and the second stripper can be separately used or be mixed before use. The photoresist stripper provides good stripping effects on photoresists currently available on the market.

Applicable types of the photoresists can include, for example but not limited to, an ADH type photoresist (containing acrylic monomers), a t-BOC type photoresist (containing tertiary butoxy carbonyl groups), and an Acetal type photoresist (containing PHS-type copolymers). These examples are provided for illustrative purposes only, and do not limit the types of applicable photoresists.

In the photoresist stripper, the first stripper is used to remove a dry film (formed from the photoresist). The second stripper is used to moisten the dry film, and has no obvious stripping effect. The moistened dry film is more likely to be removed from the circuit board by reacting with the first stripper. In other words, the second stripper can assist the first stripper to remove the dry film.

### First Stripper

The first stripper is an aqueous solution, and an organic base (an amine compound) is absent from the first stripper. The first stripper includes an inorganic base, 1 wt % to 15 wt % of a first azole compound, 2 wt % to 10 wt % of a surfactant, and water. A concentration of the inorganic base in the first stripper ranges from 30 g/L to 45 g/L. Apart from the inorganic base, the first azole compound, and the surfactant, the remaining content of the first stripper is water.

The inorganic base includes potassium hydroxide and sodium hydroxide. In the first stripper, an amount of the potassium hydroxide is higher than an amount of the sodium hydroxide. In an exemplary embodiment, a weight ratio of the potassium hydroxide to the sodium hydroxide ranges from 2.5 to 6.0, such as 3.0, 3.5, 4.0, 4.5, 5.0, or 5.5.

The concentration of the inorganic base (i.e., the potassium hydroxide and the sodium hydroxide) in the first stripper can be any real number between 30 g/L and 45 g/L. Preferably, the concentration of the inorganic base in the first stripper is 32 g/L, 34 g/L, 36 g/L, 38 g/L, 40 g/L, 42 g/L, or 44 g/L.

In the present disclosure, a preparation method of the first stripper is to respectively prepare a potassium hydroxide solution and a sodium hydroxide solution. After mixing appropriate amounts of the potassium hydroxide solution and the sodium hydroxide solution, other components (the first azole compound and the surfactant) are added. Finally, water is added to reach a final volume. Specific preparation steps will be described in examples below.

The inorganic base can help hydrolysis of esters (saponification). Therefore, the inorganic base in the first stripper can break the main chain cross-linking of the photoresist. In this way, the dry film can be peeled off and divided into multiple flakes, thereby achieving the effect of removing the dry film.

Compared to a film-dissolved mechanism of the organic base, the use of the inorganic base in the present disclosure is more beneficial for a continuous process. The peeled dry film in the form of flakes can be easily removed by filtration, so as to reduce waste disposal.

It should be noted that, when the inorganic base is used as a stripper, carboxylic acid (otherwise referred to as fatty acid soap) will be generated during saponification, and foaming is likely to occur. As such, using the stripper that contains the inorganic base in a photoresist stripping process may cause the problem of substantial foaming. When bubbles are adhered to the circuit board, the photoresist stripping effect will be reduced, thereby decreasing production efficiency and a yield.

In order to prevent excessive foaming, the surfactant is added in the present disclosure for its tendency to dissociate and form ions in a strong base environment. Hence, the structural stability of the foam will be reduced due to the ions. In this way, formation of durable foam and excessive foaming can be prevented, thereby avoiding negative impact on the photoresist stripping effect.

The above-mentioned inorganic base has strong alkalinity and a high concentration. In order to prevent the inorganic base from eroding a copper circuit, the first azole compound is added in the present disclosure to protect the copper circuit. An amount of the first azole compound in the first stripper can be any real number between 1 wt % and 15 wt %, and preferably ranges between 5 wt % and 15 wt %.

An azole compound is a compound having a five-membered heterocyclic ring. The five-membered heterocyclic ring has at least two heteroatoms on its skeleton. The at least two heteroatoms contain at least one nitrogen atom.

After experimental testing, the azole compound containing three or more nitrogen atoms on the skeleton of the five-membered heterocyclic ring is preferable, such as triazole or tetrazole. Specifically, the first azole compound can be benzotriazole (BTA), tolytriazole (TTA), or 5-phenyl-1H-tetrazole, but is not limited thereto. On the other hand, when the azole compound has a mercapto group, the azole compound can have better adhesion to copper atoms. As such, a thiazole compound containing only one nitrogen atom and one sulfur atom can be used, and the first azole compound can also be mercaptobenzothiazole.

The addition of the surfactant can enhance wettability of the first stripper. This is beneficial for the inorganic base to permeate into the copper circuit, thereby enhancing the stripping ability and speed. An amount of the surfactant in the first stripper can be any real number between 2 wt % and 10 wt %.

The addition of the surfactant can also help the first azole compound disperse in the first stripper. Generally speaking, the azole compound exhibits low solubility in water. Since the first stripper is the aqueous solution, the presence of the surfactant is necessary.

In an exemplary embodiment, the surfactant can be sodium lauryl sulfate, octadecyltrimethylammonium hydroxide, alkyl dimethylphenyl ammonium hydroxide, alkyl sulfate ester salt, sulfosuccinate ester, glutamate, lauryl betaine, cocamidopropyl betaine, or polyoxyethylene lauryl ether potassium phosphate. However, the present disclosure is not limited thereto.

### Second Stripper

The second stripper is an organic solution. An organic base (an amine compound) is absent from the second stripper. The second stripper includes 30 wt % to 80 wt % of an ether alcohol solvent, 5 wt % to 15 wt % of a second azole compound, and water. Apart from the ether alcohol solvent and the second azole compound, the remaining content of the second stripper is water.

The ether alcohol solvent can permeate the photoresist and enable swelling of the dry film, thereby facilitating removal of the dry film. In the presence of the first stripper, the ether alcohol solvent can support the dry film and provide a pathway for the inorganic base to react with the dry film, so as to improve a stripping rate.

For example, the ether alcohol solvent can be diethylene glycol butyl ether, diethylene glycol methyl ether, diethylene glycol propyl ether, dipropylene glycol propyl ether, propylene glycol n-butyl ether, diethylene glycol dibutyl ether, tripropylene glycol methyl ether, ethylene glycol butyl ether, ethylene glycol propyl ether, diethylene glycol hexyl ether, diethylene glycol diethyl ether, or diethylene glycol dimethyl ether.

The second stripper also contains an azole compound to protect the copper circuit from being eroded by the inorganic base. The applicable azole compound is similar to those mentioned above, and will not be reiterated herein. The second azole compound can be benzotriazole, mercaptobenzothiazole, tolyltriazole, or 5-phenyltetrazole. It should be noted that the first azole compound and the second azole compound can be the same or different.

### Method for Using Photoresist Stripper

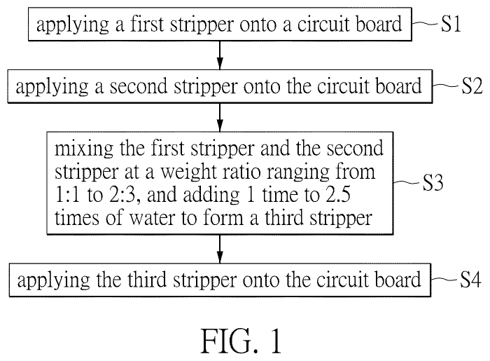

Referring to FIG. 1, the photoresist stripper of the present disclosure is the two-part photoresist stripper. When the photoresist stripper is being used, the first stripper is applied onto the circuit board to remove most of the dry film (step S1). Then, the second stripper is applied onto the circuit board for swelling of the dry film and decrease in adhesion between the dry film and the circuit board (step S2). The first stripper and the second stripper are mixed at a specific weight ratio to form a third stripper (step S3). The third stripper is applied onto the circuit board, so as to remove the remaining dry film (step S4).

The first azole compound in the first stripper can be adhered to the exposed copper circuit for protection purposes. The inorganic base can break the main chain cross-linking of the photoresist, such that the dry film is peeled off and divided into the flakes. Due to the surfactant, the flakes are dispersed in the first stripper. However, the first stripper is less likely to permeate into areas where a circuit pitch is narrow. Therefore, the second stripper is added. The second stripper enables swelling of the dry film, thereby providing a pathway for the first stripper to permeate into the areas where the circuit pitch is narrow. After the third stripper is added, the third stripper can easily permeate into the circuits having the narrow pitch, so as to strip off the remaining dry film without eroding the already formed circuits.

In the step of preparing the third stripper, the first stripper and the second stripper are weighed and mixed at a weight ratio ranging from 1:1 to 2:3. Subsequently, water is added in a weight amount equal to 1 time to 2.5 times a total weight of the first stripper and the second stripper. In this way, the third stripper is formed.

It should be noted that the third stripper is prepared from the first stripper, the second stripper, and water. Hence, the azole compound is also added in the second stripper, which ensures that a concentration of the azole compound in the formulated third stripper is sufficient to protect a copper surface.

By being prepared in the manner mentioned above, the third stripper includes an inorganic base, 1 wt % to 5 wt % of an azole compound, 1 wt % to 10 wt % of a surfactant, 30 wt % to 80 wt % of an ether alcohol solvent, and water. Apart from the inorganic base, the azole compound, the surfactant, and the ether alcohol solvent, the remaining content of the third stripper is water. A concentration of the inorganic base in the photoresist stripper ranges from 1.5 g/L to 26 g/L.

Specifically, a concentration ratio of the inorganic base in the first stripper to the inorganic base in the third stripper ranges from 1.15 times to 30 times. In an exemplary embodiment, the concentration ratio of the inorganic base in the first stripper to the inorganic base in the third stripper is a real number between 1.15 and 30.

The third stripper is primarily used for removal of the dry film that remains between the circuits having the narrow pitch. The amount of the second stripper is higher than the amount of the first stripper. In this way, swelling of the dry film can be achieved, and a pathway can be provided for the third stripper to react with the remaining dry film.

Since most of the dry film is removed, a large amount of water is added into the third stripper to prevent the exposed copper surface from being eroded. Moreover, the first azole compound and the second azole compound can protect the exposed copper surface.

It should be noted that, while the first stripper is the aqueous solution, the second stripper contains a greater amount of an organic solvent. Hence, phase separation may happen between the first stripper and the second stripper. Since the first stripper contains the surfactant, a homogeneous mixture can still be obtained when the first stripper and the second stripper are mixed.

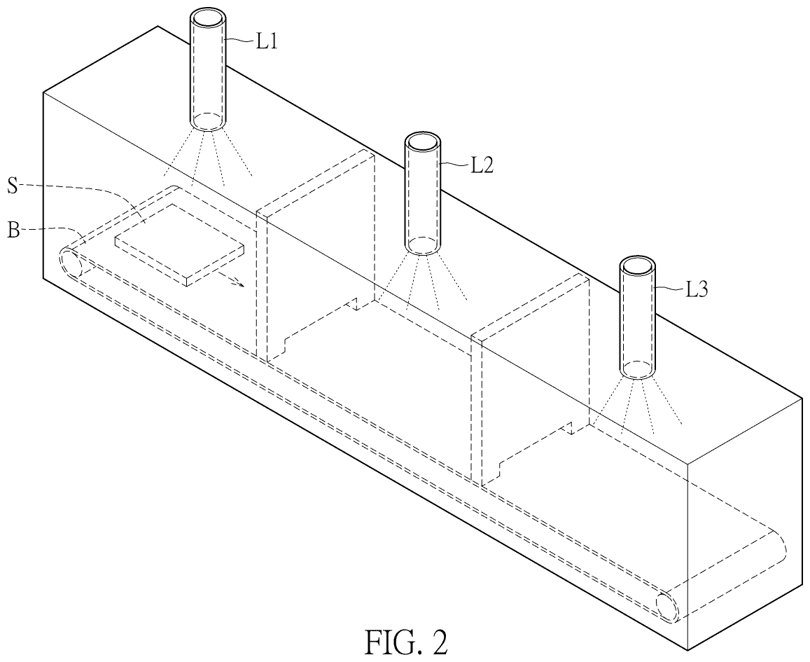

Referring to FIG. 2, a stripper is applied to a circuit board S by spraying, but the present disclosure is not limited thereto. During a stripping treatment, the circuit board S is placed on a conveyor belt B, and sequentially passes through a supply end L1 of the first stripper, a supply end L2 of the second stripper, and a supply end L3 of the third stripper. According to step S1, step S2, and step S4, the photoresist stripper is sprayed on the circuit board S for removal of the dry film.

Compared to a conventional wet batch process, applying the stripper by spraying can avoid poor stripping performances caused by re-adhesion of the stripped dry film or aging of the stripper after long-term use. In addition, by spraying the stripper, a use amount of the stripper can be reduced, and the desired effect can be achieved by a minimum use amount.

### Tests 1 to 6

In order to prove the effect of the photoresist stripper of the present disclosure, an ADH photoresist that contains acrylic monomers is used to form a dry film having a thickness of 25 μm or 30 μm on the circuit board. The specific thickness of the dry film is listed in Table 1. The first stripper, the second stripper, and the third stripper are prepared according to the contents listed in Table 1. Units that are not specifically indicated in Table 1 are parts by weight.

In Tests 1 to 6, a potassium hydroxide solution having a concentration that ranges from 45 wt % to 50 wt % and a sodium hydroxide solution having a concentration that ranges from 45 wt % to 50 wt % are prepared. After calculation, appropriate amounts of the potassium hydroxide solution and the sodium hydroxide solution are mixed, such that the first stripper can reach a target inorganic base concentration.

Specifically, the first stripper is formed by mixing 50 wt % to 85 wt % of the potassium hydroxide solution and 10 wt % to 25 wt % of the sodium hydroxide solution, but the present disclosure is not limited thereto.

In Tests 1 to 6, the first azole compound is benzotriazole, the surfactant is phosphate ester salt, the ether alcohol solvent is diethylene glycol butyl ether, and the second azole compound is benzotriazole.

After preparation of the first stripper, the second stripper, and the third stripper, three beakers are used to accommodate the first stripper, the second stripper, and the third stripper, respectively. Under conditions of a temperature of 70° C. and a rotation speed of 600 rpm, the circuit board is sequentially immersed into each of the first stripper, the second stripper, and the third stripper for 180 seconds, so as to complete the stripping treatment.

During the stripping treatment, since most of the dry film is removed in the first stripper, the required time for the circuit board to remove 80% of the dry film in the first stripper is recorded and represented as a stripping time, so as to evaluate the stripping effect of the first stripper on the dry film.

When the stripping treatment is completed, a stripping ability of the photoresist stripper is evaluated according to a residual amount of the dry film. When the residual amount of the dry film is less than 1%, the mark “O” is expressed in Table 1. When the residual amount of the dry film is greater than 1% and less than 5%, the mark “Δ” is expressed in Table 1. In addition, an oxidation status of the copper surface is evaluated based on the condition of the copper surface. When a ratio of the oxidized copper surface to the entire copper surface is less than 1%, the mark “O” is expressed in Table 1. When the ratio of the oxidized copper surface to the entire copper surface is greater than 3%, the mark “X” is expressed in Table 1.

TABLE 1

| | | Test | | | | | |
|---|---|---|---|---|---|---|---|
| (part by weight) | | 1 | 2 | 3 | 4 | 5 | 6 |
| First | Potassium | 50 | 50 | 70 | 60 | 55 | 65 |
| stripper | hydroxide | | | | | | |
| | solution | | | | | | |
| | Sodium | 10 | 15 | 20 | 15 | 20 | 15 |
| | hydroxide | | | | | | |
| | solution | | | | | | |
| | First azole | 0 | 1 | 3 | 5 | 5 | 5 |
| | compound | | | | | | |
| | Surfactant | 0 | 5 | 5 | 10 | 10 | 3 |
| | Water | 40 | 29 | 2 | 10 | 10 | 12 |
| | Concentration | 30 | 32.5 | 45 | 37.5 | 37.5 | 40 |
| | of inorganic | | | | | | |
| | base (g/L) | | | | | | |
| | Weight ratio of | 5 | 3.3 | 3.5 | 4 | 2.75 | 4.3 |
| | KOH/NaOH (—) | | | | | | |
| Second | Ether alcohol | 50 | 60 | 80 | 80 | 70 | 75 |
| stripper | solvent | | | | | | |
| | Second azole | 5 | 3 | 5 | 1 | 4 | 3 |
| | compound | | | | | | |
| | Water | 45 | 37 | 15 | 19 | 26 | 22 |
| Third | First stripper | 15 | 15 | 15 | 15 | 15 | 15 |
| stripper | Second stripper | 15 | 15 | 15 | 15 | 15 | 15 |
| | Water | 70 | 70 | 70 | 70 | 70 | 70 |
| | Concentration | 4.5 | 4.9 | 6.8 | 5.6 | 5.6 | 6.0 |
| | of inorganic | | | | | | |
| | base (g/L) | | | | | | |

| | | | | | | |
|---|---|---|---|---|---|---|
| Thickness of dry film (μm) | 25 | 25 | 30 | 30 | 30 | 30 |
| Required time for | 130 | 100 | 95 | 98 | 110 | 115 |
| removing | | | | | | |
| 80% of dry film | | | | | | |
| Stripping ability | Δ | ◯ | ◯ | ◯ | ◯ | ◯ |
| Oxidation status of copper | X | ◯ | ◯ | ◯ | ◯ | ◯ |
| surface | | | | | | |

According to the results in Table 1, the photoresist stripper of the present disclosure and the method for using the same can effectively remove the dry film on the circuit board, and allow the circuit board to maintain a good quality. According to the results of Tests 1 to 6, when the circuit board is immersed in the first stripper, 80% of the dry film can be removed in 180 seconds, which proves that the photoresist stripper of the present disclosure has a good stripping effect.

According to the results of Test 1, the addition of the first azole compound has an obvious effect on protecting the copper surface. In a strong base environment, the copper surface is likely to be eroded and oxidized without the first azole compound. In addition, the stripping ability of the photoresist stripper will be affected by the surfactant. When no surfactant is added, the first stripper cannot wet the circuit board well, thereby restricting the stripping ability.

When an amount of the inorganic base in the first stripper is high, the stripping process can be completed more quickly. However, when the amount of the inorganic base in the first stripper is overly high, excessive erosion of the circuit board may occur.

### Tests 7 to 12

Operations and evaluations of Tests 7 to 12 are similar to those of Tests 1 to 6. The difference is that: content ratios of the first stripper, the second stripper, and water in the third stripper are different. The specific components of the first stripper, the second stripper, and the third stripper are listed in Table 2. Units that are not specifically indicated in Table 2 are parts by weight.

TABLE 2

| | | Test | | | | | |
|---|---|---|---|---|---|---|---|
| (part by weight) | | 7 | 8 | 9 | 10 | 11 | 12 |
| First | Potassium | 50 | 50 | 70 | 60 | 55 | 65 |
| stripper | hydroxide | | | | | | |
| | solution | | | | | | |
| | Sodium hydroxide | 10 | 15 | 20 | 15 | 20 | 15 |
| | solution | | | | | | |
| | First azole | 0 | 1 | 3 | 5 | 5 | 5 |
| | compound | | | | | | |
| | Surfactant | 0 | 5 | 5 | 10 | 10 | 3 |
| | Water | 40 | 29 | 2 | 10 | 10 | 12 |
| | Concentration of | 30 | 32.5 | 45 | 37.5 | 37.5 | 40 |
| | inorganic base (g/L) | | | | | | |
| | Weight ratio of | 5 | 3.3 | 3.5 | 4 | 2.75 | 4.3 |
| | KOH/NaOH (—) | | | | | | |
| Second | Ether alcohol | 50 | 60 | 80 | 80 | 70 | 75 |
| stripper | solvent | | | | | | |
| | Second azole | 5 | 3 | 5 | 1 | 4 | 3 |
| | compound | | | | | | |
| | Water | 45 | 37 | 15 | 19 | 26 | 22 |
| Third | First stripper | 20 | 20 | 20 | 20 | 20 | 20 |
| stripper | Second stripper | 30 | 30 | 30 | 30 | 30 | 30 |
| | Water | 50 | 50 | 50 | 50 | 50 | 50 |
| | Concentration of | 4.5 | 4.9 | 6.8 | 5.6 | 5.6 | 6.0 |
| | inorganic base (g/L) | | | | | | |

| | | | | | | |
|---|---|---|---|---|---|---|
| Thickness of dry film (μm) | 25 | 25 | 30 | 30 | 30 | 30 |
| Required time for | 125 | 85 | 77 | 80 | 93 | 102 |
| removing | | | | | | |
| 80% of dry film | | | | | | |
| Stripping ability | Δ | ◯ | ◯ | ◯ | ◯ | ◯ |
| Oxidation status of copper | X | ◯ | ◯ | ◯ | ◯ | ◯ |
| surface | | | | | | |

According to the results in Table 2, the content ratio of the third stripper can be appropriately adjusted. The lower an amount of water in the third stripper, the shorter the required time for removing 80% of the dry film. In an exemplary embodiment, the amount of water in the third stripper ranges from 45 wt % to 75 wt %, and can be any real number between 45 wt % and 75 wt %.

### Beneficial Effects of the Embodiments

In conclusion, in the photoresist stripper and the method for using the same provided by the present disclosure, by virtue of “the first stripper including the inorganic base, the first azole compound, and the surfactant” and “the second stripper including the ether alcohol solvent and the second azole compound,” the photoresist stripper can have a good stripping effect without the addition of the organic base.

Furthermore, the first stripper of the present disclosure can be used to remove a larger area of the dry film, while the second stripper and the third stripper can be used to remove the dry film between the circuits having the narrow pitch. In this way, a good stripping effect can be achieved without using the organic base, thereby replacing the stripper currently available on the market (which uses the organic base and has irritating odors).

In addition, for users, the photoresist stripper of the present disclosure is convenient to use. Since the first stripper and the second stripper of the photoresist stripper are individually packaged, convenience in use can be obtained. Moreover, without the need to add other components, the third stripper can be easily formulated by simply weighing and adding an appropriate amount of water.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A photoresist stripper, wherein an organic base is absent from the photoresist stripper, the photoresist stripper comprising:
a first stripper including:
an inorganic base, wherein the inorganic base includes potassium hydroxide and sodium hydroxide;
1 wt % to 15 wt % of a first azole compound;
2 wt % to 10 wt % of a surfactant; and
water; and
a second stripper including:
30 wt % to 80 wt % of an ether alcohol solvent;
1 wt % to 15 wt % of a second azole compound; and
water;
wherein a concentration of the inorganic base in the first stripper ranges from 30 g/L to 45 g/L.

2. The photoresist stripper according to claim 1, wherein a weight ratio of the potassium hydroxide to the sodium hydroxide ranges from 2.5 to 6.0.

3. The photoresist stripper according to claim 1, wherein the first azole compound is selected from the group consisting of: benzotriazole, mercaptobenzothiazole, tolyltriazole, and 5-phenyltetrazole.

4. The photoresist stripper according to claim 1, wherein the second azole compound is selected from the group consisting of: benzotriazole, mercaptobenzothiazole, tolyltriazole, and 5-phenyltetrazole.

5. The photoresist stripper according to claim 1, wherein the surfactant is selected from the group consisting of: sodium lauryl sulfate, octadecyltrimethylammonium hydroxide, alkyl dimethylphenyl ammonium hydroxide, alkyl sulfate ester salt, phosphate ester salt, sulfosuccinate ester, glutamate, lauryl betaine, cocamidopropyl betaine, and polyoxyethylene lauryl ether potassium phosphate.

6. The photoresist stripper according to claim 1, wherein the ether alcohol solvent is selected from the group consisting of: diethylene glycol butyl ether, diethylene glycol methyl ether, diethylene glycol propyl ether, dipropylene glycol propyl ether, propylene glycol n-butyl ether, diethylene glycol dibutyl ether, tripropylene glycol methyl ether, ethylene glycol butyl ether, ethylene glycol propyl ether, diethylene glycol hexyl ether, diethylene glycol diethyl ether, and diethylene glycol dimethyl ether.

7. A method for using a photoresist stripper, comprising:
applying a first stripper onto a circuit board, wherein an organic base is absent from the first stripper, and the first stripper includes an inorganic base, 1 wt % to 15 wt % of a first azole compound, 2 wt % to 10 wt % of a surfactant, and water; wherein a concentration of the inorganic base in the first stripper ranges from 30 g/L to 45 g/L;
applying a second stripper onto the circuit board, wherein an organic base is absent from the second stripper, and the second stripper includes 30 wt % to 80 wt % of an ether alcohol solvent, 1 wt % to 15 wt % of a second azole compound, and water;
mixing the first stripper and the second stripper at a weight ratio ranging from 1:1 to 2:3, and adding 1 time to 2.5 times of water to form a third stripper; and
applying the third stripper onto the circuit board.

8. The method according to claim 7, wherein the first stripper, the second stripper, and the third stripper are applied to the circuit board by spraying.

9. A photoresist stripper, wherein an organic base is absent from the photoresist stripper, the photoresist stripper comprising:
an inorganic base, wherein the inorganic base includes potassium hydroxide and sodium hydroxide;
1 wt % to 5 wt % of an azole compound;
1 wt % to 10 wt % of a surfactant;
30 wt % to 80 wt % of an ether alcohol solvent; and
water;
wherein a concentration of the inorganic base in the photoresist stripper ranges from 1.5 g/L to 26 g/L.

10. The photoresist stripper according to claim 9, wherein the azole compound includes at least one of benzotriazole, mercaptobenzothiazole, tolyltriazole, and 5-phenyltetrazole.
